(19) United States
(12) Patent Application Publication
(10) Pub. No.: US 2024/0167191 A1
(43) Pub. Date: May 23, 2024

(54) INGOT PULLER APPARATUS HAVING A REFLECTOR ASSEMBLY SUSPENDED FROM SUPPORT SHAFTS

(71) Applicant: GlobalWafers Co., Ltd., Hsinchu (TW)

(72) Inventors: Benjamin Michael Meyer, Defiance, MO (US); Carissima Marie Hudson, St. Charles, MO (US); JaeWoo Ryu, Plano, TX (US)

(21) Appl. No.: 18/507,219

(22) Filed: Nov. 13, 2023

Related U.S. Application Data
(60) Provisional application No. 63/426,977, filed on Nov. 21, 2022.

(51) Int. Cl. C30B 15/14; C30B 29/06

(52) U.S. Cl. CPC C30B 15/14; C30B 29/06

(57) ABSTRACT

Ingot puller apparatus having a reflector assembly suspended from support shafts are disclosed. Each support shaft may be connected to a joist. The joist is connected to the flange of the reflector assembly by two flexible joints that are separated from each other along a longitudinal axis of the joist.

### CROSS-REFERENCE TO RELATED APPLICATION

This application claims the benefit of U.S. Provisional Patent Application No. 63/426,977, filed Nov. 21, 2022, which is incorporated herein by reference in its entirety.

### FIELD OF THE DISCLOSURE

The field of the disclosure relates to ingot puller apparatus having a reflector assembly suspended from support shafts that extend above the reflector assembly.

### BACKGROUND

Single crystal silicon ingots may be grown by the so-called Czochralski process in which a silicon seed crystal is contacted with a melt of silicon. The silicon seed crystal is withdrawn from the melt causing a single crystal silicon ingot suspended by the seed crystal to form. The silicon seed crystal is secured to a seed chuck that is connected to a pull cable. The pull cable supports the chuck and seed crystal (and ingot during crystal growth). The pull cable is connected to a pulling mechanism which lowers and raises the pull cable within the ingot puller apparatus.

As the single crystal silicon ingot is withdrawn from the melt, the ingot may pass through a reflector assembly which redirects heat back toward the ingot. Conventionally, reflector assemblies are supported by a series of graphite parts that are vertically stacked in the hot-zone. During meltdown of the solid-state polycrystalline silicon, the graphite parts thermally expand which results in an unpredictable axial position of the reflector assembly.

A need exists for an ingot puller apparatus in which the reflector assembly is predictably and repeatedly positioned in the ingot puller apparatus while maintaining the integrity and lifetime of components used to support the reflector assembly.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to an ingot puller apparatus for producing a single crystal silicon ingot. The ingot puller apparatus includes a crucible assembly for holding a silicon melt. A crystal puller housing defines a growth chamber for pulling a silicon ingot from the silicon melt. The crucible assembly is disposed within the growth chamber. A reflector assembly has an opening for receiving the single crystal silicon ingot as the ingot is pulled through the reflector assembly. The reflector assembly includes an upper flange and a shield that extends downward from the upper flange. The ingot puller apparatus includes two or more support shafts for supporting the reflector assembly. The support shafts extending upward from the reflector assembly. The ingot puller apparatus includes two or more joists. Each joist is connected to a support shaft toward a lower end of the support shaft. Each joist is connected to the flange by first and second joints that are separated from each other along a longitudinal axis of the joist.

Another aspect of the present disclosure is directed to an ingot puller apparatus for producing a single crystal silicon ingot. The ingot puller apparatus includes a crucible assembly for holding a silicon melt. A crystal puller housing defines a growth chamber for pulling a silicon ingot from the silicon melt. The crucible assembly is disposed within the growth chamber. The ingot puller apparatus includes a reflector assembly having an opening for receiving the single crystal silicon ingot as the ingot is pulled through the reflector assembly. The reflector assembly includes an upper flange and a shield that extends downward from the upper flange. The ingot puller apparatus includes first and second support shafts for supporting the reflector assembly. The first and second support shafts extend upward from the reflector assembly. The ingot puller apparatus does not include more than two support shafts. Each support shaft is connected to the crystal puller housing at a support shaft port.

Yet another aspect of the present disclosure is directed to an ingot puller apparatus for producing a single crystal silicon ingot. The ingot puller apparatus incudes a crucible assembly for holding a silicon melt. A crystal puller housing defines a growth chamber for pulling a silicon ingot from the silicon melt. The crucible assembly is disposed within the growth chamber. A reflector assembly has an opening for receiving the single crystal silicon ingot as the ingot is pulled through the reflector assembly. The reflector assembly includes an upper flange and a shield that extends downward from the upper flange. The ingot puller apparatus includes first and second support shafts for supporting the reflector assembly. The first and second support shafts extend upward from the reflector assembly. Each support shaft is connected to the upper flange by a flexible joint.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a is a cross-section of an ingot puller apparatus during ingot growth;

FIG. 2 is a schematic of an ingot puller apparatus having an upper segment and lower segment that is removably connected to the upper segment;

FIG. 3 is a perspective view of a reflector assembly of the ingot puller apparatus;

FIG. 4 is a perspective view of a support shaft and joist of the ingot puller apparatus showing two joints for connecting the joist to the reflector assembly;

FIG. 5 is an exploded perspective view of first and second casings, pins and an outer shell for connecting the support shaft to the joist;

FIG. 6 is a cross-section view front view of a joint for connecting the joist to the reflector assembly;

FIG. 7 is a front view of the support shaft and joist connected to the flange of the reflector assembly; and

FIG. 8 is a cross-section view of an outer gas shield and flange of the reflector assembly.

Corresponding reference characters indicate corresponding parts throughout the drawings.

### DETAILED DESCRIPTION

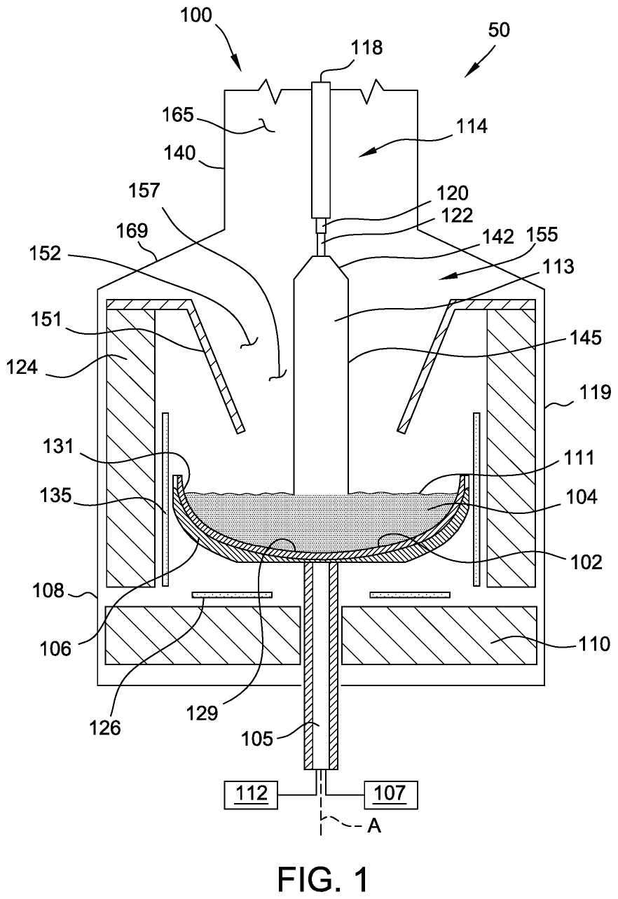

Provisions of the present disclosure relate to ingot puller apparatus having a reflector assembly that is suspended from support shafts that extend upward from the reflector assembly (i.e., that hangs from the support shafts). An example ingot puller apparatus (or more simply “ingot puller”) is indicated generally as “100” in FIG. 1. The ingot puller apparatus 100 includes a crucible assembly 102 for holding a melt 104 of semiconductor or solar-grade material silicon. The crucible assembly 102 is supported by a susceptor 106.

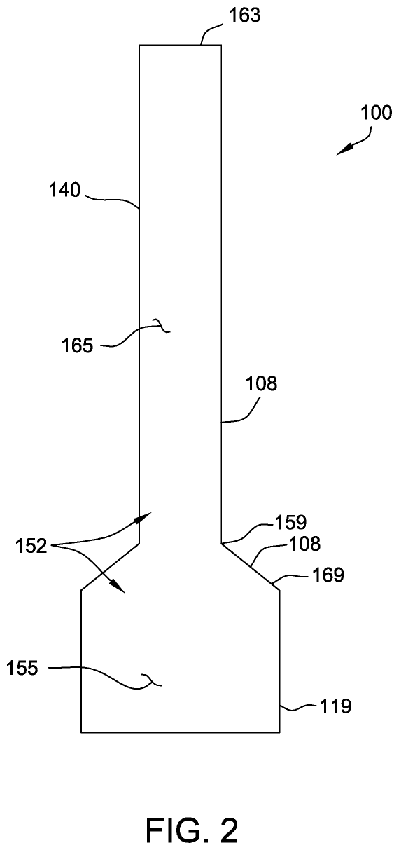

The ingot puller apparatus 100 includes a crystal puller housing 108 that defines a growth chamber 152 for pulling a silicon ingot from the silicon melt 104 along a pull axis A. Referring now to FIG. 2, the growth chamber 152 includes two portions—a lower growth chamber 155 (or simply “lower chamber”) and an upper growth chamber 165 (or simply “upper chamber”) disposed above the lower growth chamber 155. The hotzone of the ingot puller apparatus 100 (e.g., crucible, reflector assembly, susceptor, heaters, and the like) is disposed within the lower chamber 155. During ingot growth, the ingot 113 is pulled through the lower chamber 155 and continues to be pulled through the upper chamber 165 as the ingot lengthens.

The crystal puller housing 108 includes a domed lower segment 119 that defines the lower chamber 155 and an upper segment 140 that defines the upper chamber 165. The lower domed segment 119 includes a dome-shaped portion 169 which tapers in size to the diameter of the upper segment 140. The upper segment 140 is generally cylindrical in shape and includes a lower end 159 and an upper end 163. The upper segment 140 of the crystal puller housing 108 is removably connected to the lower segment 119 (e.g., by fasteners, gaskets or the like).

The crucible assembly 102 (FIG. 1) is disposed in the lower chamber 155. The crucible assembly 102 has a sidewall 131 and floor 129 and rests on a susceptor 106. The susceptor 106 is supported by a shaft 105. The susceptor 106, crucible assembly 102, shaft 105, and ingot 113 have a common longitudinal axis or “pull axis” A.

A pulling mechanism 114 is provided within the ingot puller apparatus 100 for growing and pulling an ingot 113 from the melt 104. The pulling mechanism 114 includes a pull cable 118, a seed holder or chuck 120 coupled to one end of the pull cable 118, and a seed crystal 122 coupled to the chuck 120 for initiating crystal growth. One end of the pull cable 118 is connected to a pulley (not shown) or a drum (not shown) of the pulling mechanism 114 and the other end is connected to the chuck 120 that holds the seed crystal 122. The pulling mechanism 114 includes a motor that rotates the pulley or drum.

In operation, the seed crystal 122 is lowered to contact the surface 111 of the melt 104. The pulling mechanism 114 is operated to cause the seed crystal 122 to rise. This causes a single crystal ingot 113 to be pulled from the melt 104.

During heating and crystal pulling, a crucible drive unit 107 (e.g., a motor) rotates the crucible assembly 102 and susceptor 106. A lift mechanism 112 raises and lowers the crucible assembly 102 along the pull axis A during the growth process. For example, the crucible assembly 102 may be at a lowest position (near the bottom heater 126) in which a charge of solid-phase silicon 133 previously added to the crucible assembly 102 is melted. Crystal growth commences by contacting the melt 104 with the seed crystal 122 and lifting the seed crystal 122 by the pulling mechanism 114.

A crystal drive unit (not shown) may also rotate the pulling cable 118 and ingot 113 in a direction opposite the direction in which the crucible drive unit 107 rotates the crucible assembly 102 (e.g., counter-rotation). In embodiments using iso-rotation, the crystal drive unit may rotate the pulling cable 118 in the same direction in which crucible drive unit rotates the crucible assembly 102.

The ingot puller apparatus 100 includes bottom insulation 110 and side insulation 124 to retain heat in the puller apparatus 100. In the illustrated embodiment, the ingot puller apparatus 100 includes a bottom heater 126 disposed below the crucible floor 129. The crucible assembly 102 may be moved to be in relatively close proximity to the bottom heater 126 to melt the solid silicon charged to the crucible assembly 102.

According to the Czochralski single crystal growth process, a quantity of solid-phase silicon such as polycrystalline silicon, or “polysilicon”, is initially charged to the crucible assembly 102. The semiconductor or solar-grade solid silicon that is introduced into the crucible assembly 102 is melted by heat provided from one or more heating elements. Once the melt 104 is fully formed, the seed crystal 122 is lowered and contacted with the surface 111 of the melt 104. The pulling mechanism 114 is operated to pull the seed crystal 122 from the melt 104. The resulting ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104.

The crystal growth process may be a batch process in which solid silicon is initially added to the crucible assembly 102 to form a silicon melt without additional solid-silicon being added to the crucible assembly 102 during crystal growth. In other embodiments, the crystal growth process is a continuous Czochralski process in which an amount of silicon is added the crucible assembly during ingot growth.

The ingot puller apparatus 100 includes a side heater 135 and a susceptor 106 that encircles the crucible assembly 102 to maintain the temperature of the melt 104 during crystal growth. The side heater 135 is disposed radially outward to the crucible sidewall 131 as the crucible assembly 102 travels up and down the pull axis A. The side heater 135 and bottom heater 126 may be any type of heater that allows the side heater 135 and bottom heater 126 to operate as described herein. In some embodiments, the heaters 135, 126 are resistance heaters. The side heater 135 and bottom heater 126 may be controlled by a control system (not shown) so that the temperature of the melt 104 is controlled throughout the pulling process.

The ingot puller apparatus 100 may include a reflector assembly 151. The reflector assembly 151 includes an opening 157 through which the single crystal silicon ingot 113 is pulled during ingot growth. The ingot puller apparatus 100 may include an inert gas system to introduce and withdraw an inert gas such as argon from the growth chamber 152.

The illustrated ingot puller apparatus 100 is an example and any ingot puller apparatus 100 that includes a reflector assembly 151 may be used unless stated otherwise.

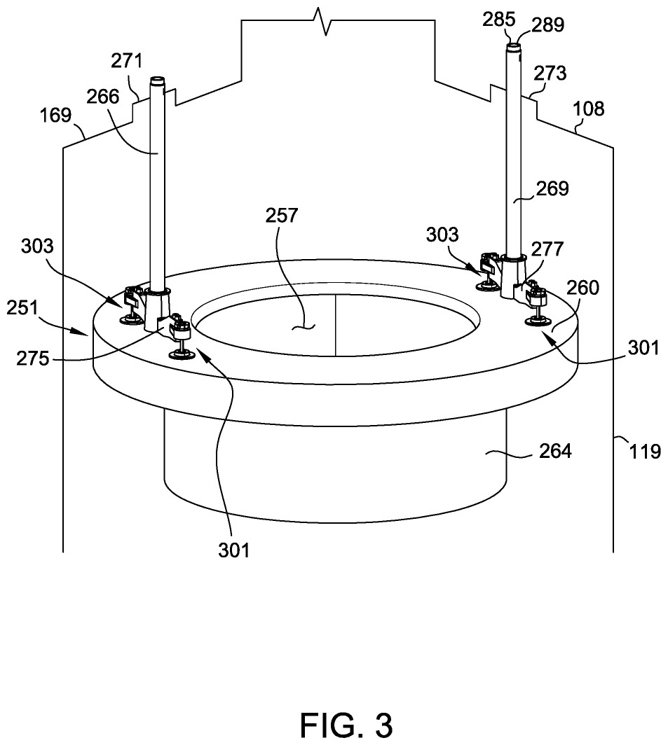

An embodiment of a reflector assembly 251 is shown in FIGS. 3-8. The reflector assembly 251 includes an upper flange 260 (or simply “flange”) and a shield 264 that extends downward from the upper flange 260. The reflector assembly 251 includes an opening 257 through which the single crystal silicon ingot is pulled. The reflector assembly 251 may include various components which together form the flange and/or shield including various plates and bands (e.g., the flange may be made of various support plates that support the various insulated components). The shield 264 may comprise insulation an outer cap that reduces or eliminates particles from dislodging from the shield 264 into the melt.

The ingot puller apparatus 100 includes two or more support shafts 266, 269 (e.g., first and second support shafts 266, 269) that extend upward from the reflector assembly 251 and support the reflector assembly 251. While the illustrated embodiment includes two support shafts 266, 269, more than two support shafts may be used in other embodiments (e.g., three, four, five or more support shafts). In other embodiments such as the illustrated embodiment, the ingot puller apparatus includes only two support shafts 266, 269. In some embodiments, during ingot growth, the reflector assembly 251 is not supported by any structure other than support shafts (e.g., in embodiments having only two support shafts or embodiments having more than two support shafts). In other embodiments, the reflector is supported by a number of shafts during installation and removal and is lowered onto a traditional graphite support prior to starting crystal growth.

The support shafts 266, 269 extend through the crystal puller housing 108 at support shaft ports 271, 273. A translation mechanism (not shown) such as bellows and a ball screw may be used to move the support shafts 266, 269 and adjust the position of the reflector assembly 251 up and down relative to the pull axis A (FIG. 1) (e.g., such as during installation or tear-down of the hotzone). The support shafts 266, 269 may be cooled (e.g., water cooled) by passing a fluid downward through the rods through an inlet 285 and returning the fluid upward through the shaft and through an outlet 289. The shafts 266, 269 may include inner pipes and/or baffles for circulating the fluid. In other embodiments, the shafts 266, 269 are solid rods. In yet other embodiments, the shafts 266, 269 are wires or cables. The shafts 266, 269 may be made of any material suitable in the environment of an ingot puller apparatus and, in some embodiments, are made of stainless steel or carbon fiber composite (CFC).

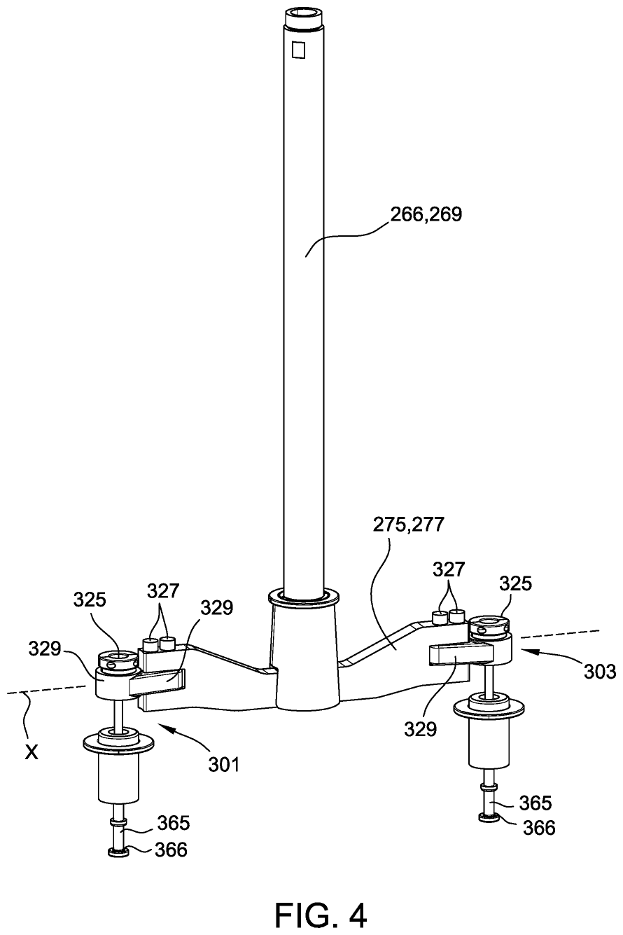

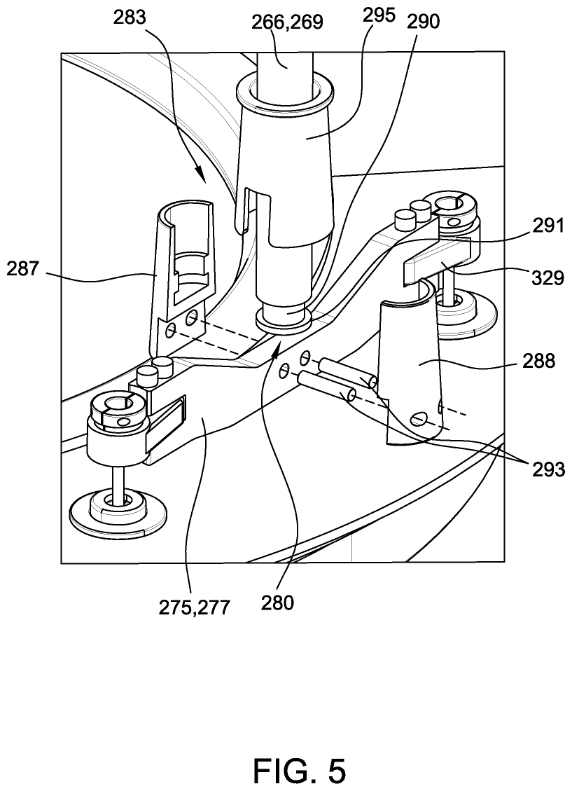

The ingot puller apparatus includes two or more joists 275, 277 (e.g., a joist for each support shaft). Each joist 275, 277 has a longitudinal axis X (FIG. 4). Each joist 275, 277 is connected to a respective support shaft 266, 269 toward a lower end 280 (FIG. 5) of the support shaft 266, 269. Referring to FIG. 5, the support shaft 266, 269 may be connected to the joist 275, 277 by a fastener 283. The illustrated fastener 283 includes two casings 287, 288 that together form an internal cavity having a profile that matches the profile of the support shaft 266, 269 toward its lower end 280. The support shaft 266, 269 may include a recess 290 and a rim 291 to facilitate capture by the casings 287, 288. The casings 287, 288 may be connected to the joist 275, 277 by one or more pins 293. The casings 287, 288 and pins 293 may be held in place by an outer shell 295. In some embodiments, the joist 275, 277 is connected to the support shaft 266, 269 by a clamp (not shown) or is welded to the support shaft 266, 269. In yet other embodiments, the respective joist 275, 277 and support shaft 266, 269 are integral (e.g., formed or molded together).

Referring back to FIG. 4, each joist 275, 277 is connected to the flange 260 (FIG. 3) of the reflector assembly 251 by first and second joints 301, 303. The joints 301, 303 are separated from each other along the longitudinal axis X of the joist 275, 277. While two joints 301, 303 are shown in the illustrated embodiment to connect each joist 275, 277 to the flange 260 (FIG. 3), in other embodiments more than two joints may be used. The first and second joints 301, 303 are flexible joints to accommodate for thermal expansion of the reflector assembly 251 during heating (and contraction during cooling). Any suitable joint that allows for radial movement of the reflector assembly 251 may be used. In the illustrated embodiment, each joint 301, 303 comprises two ball and socket joints. In other embodiments, a single ball and socket joint could be used. In other embodiments, the joint (e.g., top or bottom) comprises a wire or cable. In yet other embodiments the joint includes cylinders or cam bodies (e.g., as a substitute for the ball). The joint may include two connections with the top connection being a flexible joint and the bottom connection including a pin through a shaft, a clamp, or a collet).

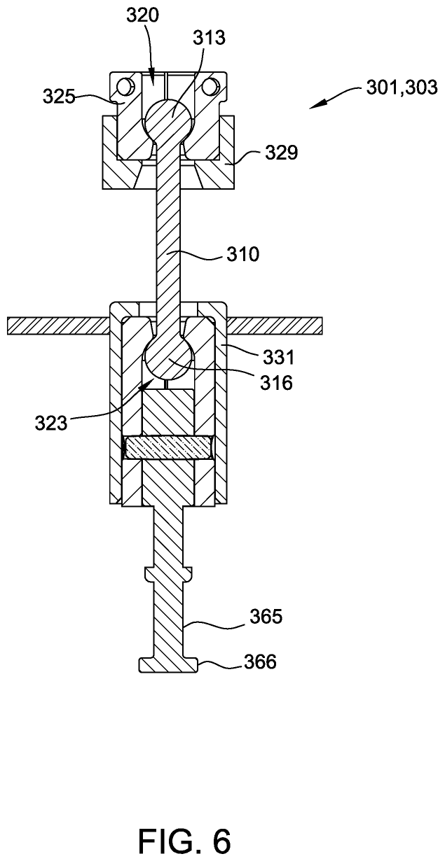

The two joints 301, 303 may be identical and an exemplary joint 301, 303 is shown in FIG. 6. Each joint 301, 303 includes a stud 310 and first and second ball members 313, 316 that extend from each end of the stud 310. The first ball member 313 is disposed within a first socket 320. A first socket housing 325 defines the first socket 320. The first socket housing 325 is secured to a linkage 329 (FIG. 4) that is connected to the joist 275, 277 by pins 327. The second ball member 316 is disposed within a second socket 323. A second socket housing 331 defines the second socket 323.

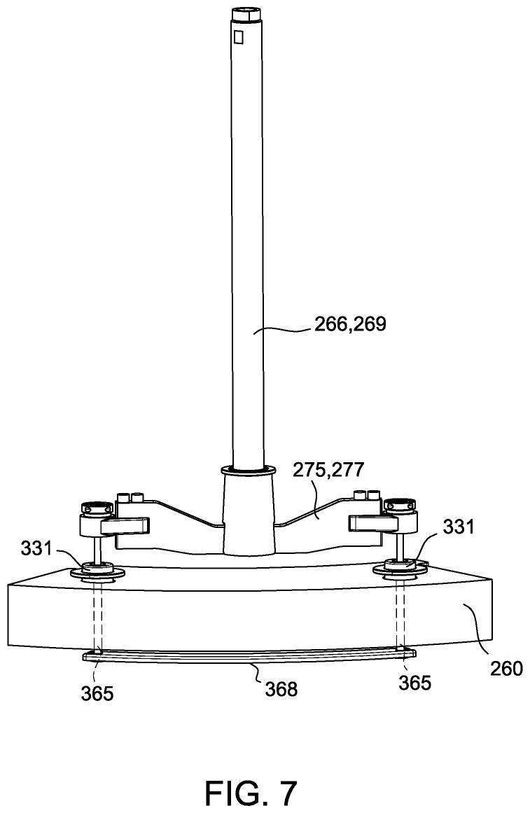

As shown in FIG. 7, the second socket housing 331 of each joint 301, 303 extends through the flange 260 of the reflector assembly 251. A rod 365 (FIG. 6) extends from the second socket housing 331. Each rod 365 is received within a support band 368 disposed below the flange 260. The support band 368 rests on a ledge 366 (FIG. 6) of each rod 365. The support band 368 may be disposed within a groove (not shown) formed in the bottom surface of the flange 260. The two support bands 368 support the weight of the reflector assembly 251.

The joints 301, 303 and their components may be made of any material that allows the joints to operate as described herein, such as, for example, molybdenum or CFC. The casings 287, 288, outer shell 295, support band 368, may also be made of molybdenum or CFC.

In some embodiments, each support band 368 does not span the two support rods 364. For example, each support band 368 may be a washer member (or other shape). In addition or as an alternative to the support band, the hanging assembly includes a ball that fits within a socket cutout of the flange 260 (without breaking through the flange 260) or a threaded connection is used (e.g., threaded shaft connection for the shaft through the flange with a nut to support the weight).

In some embodiments, the ingot puller apparatus does not include clamps for supporting the reflector assembly.

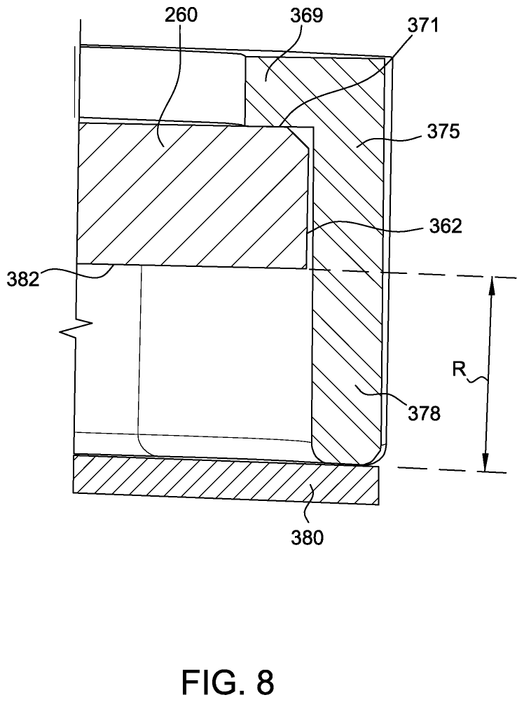

Referring now to FIG. 8, the ingot puller apparatus 100 includes an outer gas shield 375 that contacts and is radially outward of the flange 260. The outer gas shield 375 abuts an outer circumferential edge 362 of the flange 260. The outer gas shield 375 includes a leg 369 that extends from a body 378 of the outer gas shield 375. The leg 369 is disposed above a top surface 371 of the flange 260. When the reflector assembly 251 is in a raised position relative to the pull axis A, the leg 369 rests on the top surface 371 of the flange 260. As the reflector assembly 251 is lowered and as shown in FIG. 8, the outer gas shield body 378 contacts a ledge 380 of the ingot puller apparatus 100. In this position, the outer gas shield 375 prevents process gas from moving further inward into the ingot puller apparatus 100. The reflector assembly 251 may continue to be lowered causing the flange 260 to move downward relative to the outer gas shield 375 which is prevented from being lowered by the ledge 380. The reflector assembly 251 may be lowered until the bottom surface 382 of the flange 260 contacts the ledge 380. In this arrangement there is a region R through which the bottom surface 382 of the flange 260 may move with the outer gas shield 375 continuing to act as a seal to prevent process gas from moving through the ingot puller apparatus 100 (e.g., the components below the reflector assembly 251).

The outer gas shield 375 and parts of the flange 260 (e.g., parts that support the insulating components) may be made of any suitable material that allows the parts to function as described herein such as, for example, graphite. The reflector assembly 251 should be distinguished from other hot zone components such as cooling jackets in which cooling fluid is circulated throughout the jacket for cooling of the ingot.

The reflector assembly 251 may be removed from the ingot puller apparatus 100 (e.g., for cleaning) in a number of ways. For example, the reflector assembly 251 may be removed from the ingot puller apparatus 100 by (1) disconnecting the linkages 329 from each respective joist 275, 277, (2) disconnecting the support shafts 266, 269 from each respective joist 275, 277, (3) lowering the support shafts 266, 269 while supporting the reflector assembly 251 from the bottom to allow the ball member 313 to rise above the first socket housing 325 to allow the two halves of the first socket housing 325 to be separated from each other to allow the ball member 313 to pass through the linkage 329 upon lowering, or (4) supporting the reflector assembly 251 to remove load form the lower bands 368 and then sliding the bands 368 away and raising the support shafts 266, 269 away from the reflector assembly 251.

Compared to conventional ingot puller apparatus, the ingot puller apparatus of the present disclosure have several advantages. By hanging the reflector assembly, ingot puller components below the reflector assembly do not affect its vertical position during thermal expansion (e.g., stacked graphite parts below the reflector assembly) which allows for a more predictable and repeatable position of the reflector assembly. By using flexible joints (e.g., ball and socket joints) in the connection between the support shaft and the reflector assembly, radial and axially expansion of the reflector assembly may be accommodated thereby improving the structural integrity and lifetime of the reflector assembly and support shafts. The flexible joints also allow the center of the reflector assembly to stay at a consistent position and reduce or eliminate “rocking” of the reflector assembly. Embodiments using rigid support tubes or rods also reduce rocking of the reflector assembly.

In embodiments in which the ingot puller apparatus includes only two support shafts that extend through the ingot puller housing, the ingot puller housing may include only two ports which simplifies the ingot puller apparatus design. In embodiments in which the support shafts are water cooled, the support shafts undergo less thermal expansion which maintains the axial position of the reflector assembly. The reflector assembly may also be removed from the ingot puller apparatus (e.g., for cleaning) relatively easily.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment (s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. An ingot puller apparatus for producing a single crystal silicon ingot, ingot puller apparatus comprising:
a crucible assembly for holding a silicon melt;
a crystal puller housing that defines a growth chamber for pulling a silicon ingot from the silicon melt, the crucible assembly being disposed within the growth chamber,
a reflector assembly having an opening for receiving the single crystal silicon ingot as the ingot is pulled through the reflector assembly, the reflector assembly comprising:
an upper flange; and
a shield that extends downward from the upper flange;
two or more support shafts for supporting the reflector assembly, the support shafts extending upward from the reflector assembly; and
two or more joists, each joist being connected to a support shaft toward a lower end of the support shaft, each joist being connected to the flange by first and second joints that are separated from each other along a longitudinal axis of the joist.

2. The ingot puller apparatus as set forth in claim 1 wherein only two support shafts support the reflector assembly.

3. The ingot puller apparatus as set forth in claim 1 wherein, during ingot growth, the reflector assembly is not supported in the ingot puller apparatus by any structure other than support shafts.

4. The ingot puller apparatus as set forth in claim 1 wherein the first joint and second joint is each a flexible joint.

5. The ingot puller apparatus as set forth in claim 4 wherein each flexible joint is a ball and socket joint.

6. The ingot puller apparatus as set forth in claim 5 wherein each flexible joint comprises two ball and socket joints.

7. The ingot puller apparatus as set forth in claim 1 wherein the two or more support shafts are water cooled, each support shaft comprising an inlet for adding water to the support shaft and an outer for removing water from the support shaft.

8. The ingot puller apparatus as set forth in claim 1 comprising an outer gas shield, the outer gas shield abutting an outer circumferential edge of the flange.

9. The ingot puller apparatus as set forth in claim 1 wherein each support shaft extends through the crystal puller housing at a support shaft port.

10. The ingot puller apparatus as set forth in claim 1 comprising a support band disposed below the flange for supporting the reflector assembly.

11. An ingot puller apparatus for producing a single crystal silicon ingot, ingot puller apparatus comprising:
a crucible assembly for holding a silicon melt;
a crystal puller housing that defines a growth chamber for pulling a silicon ingot from the silicon melt, the crucible assembly being disposed within the growth chamber,
a reflector assembly having an opening for receiving the single crystal silicon ingot as the ingot is pulled through the reflector assembly, the reflector assembly comprising:
an upper flange; and
a shield that extends downward from the upper flange; and
first and second support shafts for supporting the reflector assembly, the first and second support shafts extending upward from the reflector assembly, the ingot puller apparatus not comprising more than two support shafts, each support shaft being connected to the crystal puller housing at a support shaft port.

12. The ingot puller apparatus as set forth in claim 11 wherein, during ingot growth, the reflector assembly is not supported in the ingot puller apparatus by any structure other than support shafts.

13. The ingot puller apparatus as set forth in claim 11 wherein each support shaft is connected to the upper flange by at least one flexible joint.

14. The ingot puller apparatus as set forth in claim 11 comprising an outer gas shield and wherein the upper flange comprises a support plate, the outer gas shield abutting an outer circumferential edge of the support plate.

15. The ingot puller apparatus as set forth in claim 11 wherein the first and second support shafts are water cooled, each support shaft comprising an inlet for adding water to the support shaft and an outer for removing water from the support shaft.

16. The ingot puller apparatus as set forth in claim 11 comprising a support band disposed below the flange for supporting the reflector assembly.

17. An ingot puller apparatus for producing a single crystal silicon ingot, the ingot puller apparatus comprising:
a crucible assembly for holding a silicon melt;
a crystal puller housing that defines a growth chamber for pulling a silicon ingot from the silicon melt, the crucible assembly being disposed within the growth chamber,
a reflector assembly having an opening for receiving the single crystal silicon ingot as the ingot is pulled through the reflector assembly, the reflector assembly comprising:
an upper flange;
a shield that extends downward from the upper flange; and
first and second support shafts for supporting the reflector assembly, the first and second support shafts extending upward from the reflector assembly, each support shaft being connected to the upper flange by a flexible joint.

18. The ingot puller apparatus as set forth in claim 17 comprising an outer gas shield and wherein the upper flange comprises a support plate, the outer gas shield abutting an outer circumferential edge of the support plate.

19. The ingot puller apparatus as set forth in claim 17 wherein the first and second support shafts are water cooled, each support shaft comprising an inlet for adding water to the support shaft and an outer for removing water from the support shaft.

20. The ingot puller apparatus as set forth in claim 17 comprising a support band disposed below the flange for supporting the reflector assembly.
